(19) United States
(12) Patent Application Publication
(10) Pub. No.: US 2019/0316245 A1
(43) Pub. Date: Oct. 17, 2019

(54) VAPOR DEPOSITION MASK AND DISPLAY DEVICE

(71) Applicant: Sharp Kabushiki Kaisha, Sakai City, Osaka (JP)

(72) Inventor: Kenta NAKAMURA, Sakai City (JP)

(21) Appl. No.: 16/472,917

(22) PCT Filed: Sep. 29, 2017
(86) PCT No.: PCT/JP2017/035417

§ 371 Date: Jun. 24, 2019

(51) Int. Cl. C23C 14/04; H01L 51/00

(52) U.S. Cl. CPC C23C 14/042; H01L 51/5012; H01L 51/001; H01L 51/0011

(57) ABSTRACT

Each of two divided masks next to each other in a second direction includes an overlapping region where two unit mask members partially overlap each other in a planar view, and a pitch in the second direction between openings on a plurality of divided masks each including the overlapping region is the same as a pitch in the second direction between the opening on each of a plurality of divided masks.

### TECHNICAL FIELD

The disclosure relates to a vapor deposition mask, a manufacturing method of a vapor deposition mask, a manufacturing method of a display device, and a display device formed using the vapor deposition mask.

### BACKGROUND ART

In recent years, various flat display panels have been developed, and particularly, an Electro luminescence (EL) display device has been receiving a lot of attention as a flat display panel excellent in that power consumption reduction, thinning, high higher-quality picture, and the like can be achieved.

Examples of the EL display device include organic Electro Luminescence (EL) displays equipped with Organic Light Emitting Diodes (OLED), EL displays such as inorganic EL displays equipped with inorganic light emitting diodes, and QLED displays equipped with Quantum dot Light Emitting Diodes (QLED) displays.

In a manufacturing process of such an EL display device, a vapor deposition film including a highly fine light-emitting layer is formed on a substrate and a highly fine vapor deposition mask is required, and therefore, the highly fine vapor deposition mask is highly demanded.

PTL 1 describes a stretching process in which a tension is applied to a vapor deposition mask for large display device.

FIG. 7A is a diagram illustrating a condition where a tension is applied to a vapor deposition mask for large display device.

As illustrated in FIG. 7A, opposite sides of a metal mask 140 for a large display device on which a metal mask 110 and a resin plate 130 are layered, are held by holding parts 180 (clamps), and drive means 185 such as a motor or an air cylinder coupled to each holding part 180 is operated to pull the holding part 180 as illustrated by arrows so that a tension is applied to the metal mask 140 for large display device.

PTL 1 describes that tension is applied to a mask for large display device when a pattern is formed on the resin plate 130 in the metal mask 140 or when the metal mask 140 is fixed to a metal frame.

On the other hand, regarding size increase of the vapor deposition mask, a vapor deposition mask has been proposed in which a plurality of unit mask members 122 (also referred to as divided masks) elongated shaped in a first direction are fixed to a mask frame 102 having frame-shape including a large opening 102a at a center part thereof, as illustrated in FIG. 7B and FIG. 7C.

FIG. 7B is a diagram illustrating a schematic configuration of the mask frame 102, and FIG. 7C is a diagram illustrating a schematic configuration of a large vapor deposition mask 100.

As illustrated in FIG. 7B, a plurality of a howling sheets 103 elongated in a second direction and a plurality of cover sheets 104 elongated in the first direction are intersected with each other and fixed to the mask frame 102.

As illustrated in FIG. 7C, the unit mask members 122 elongated shaped in the first direction 122 are fixed to the mask frame 102 in such a way that a plurality of opening groups 122a on each of the unit mask members 122 elongated shaped in the first direction 122 overlap the opening 102a of the mask frame 102 in a planar view, but do not overlap the howling sheet 103 or the cover sheet 104.

### CITATION LIST

### Patent Literature

PTL 1: JP 2015-28204 A (published on Feb. 12, 2015).

### SUMMARY

### Technical Problem

However, in the case of the metal mask 140 illustrated in FIG. 7A disclosed in PTL 1, the mask can be used as a vapor deposition mask for large display device, but a size of the mask to which a tension is applied is large, leading to the following problems.

Since a size of the mask to which a tension is applied is large, in a stretching process, the number of drive means 185 such as the motors or the air cylinders coupled to the holding parts 180 needs to be increased in order to ensure accuracy of the process, and therefore, the cost of a stretching machine used in the stretching process increases.

For the metal mask 140, which is fixed to the metal frame in a state where tension is being applied, it is required that no sagging is caused, but the sagging cannot be prevented as the size of the metal mask 140 becomes large under existing conditions.

On the other hand, in the case of the vapor deposition mask in which a plurality of unit mask members 122 (also referred to as the divided masks) elongated shaped in the first direction are fixed to the mask frame 102 having frame-shape including the large opening 102a at the center part thereof, as illustrated in FIG. 7B and FIG. 7C, it is difficult to form an opening continuously in the first direction and the second direction because of existence of the howling sheet 103 and the cover sheet 104, and therefore, this vapor deposition mask is not suitable for a vapor deposition mask for large display device.

The disclosure has been made in light of the foregoing, and has an object to provide a vapor deposition mask for large display device relatively inexpensive, a manufacturing method thereof, and a manufacturing method of a large display device.

### Solution to Problem

In order to solve the above problems, a vapor deposition mask according to the disclosure includes a mask frame having a frame-shape including an opening, and a plurality of unit mask members, each unit mask member including a plurality of openings and having a length in a first direction longer than a length in a second direction perpendicular to the first direction, each of the plurality of unit mask members being fixed to the mask frame, wherein in the plurality of unit mask members, each of two unit mask members next to each other in the second direction includes an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members.

According to the configuration described above, a vapor deposition mask for a relatively inexpensive large display device can be achieved.

In order to solve the above problems, a manufacturing method of a vapor deposition mask according to the disclosure includes a fixing step for fixing each of a plurality of unit mask members to a mask frame having frame-shape including an opening with a tension being applied in the first direction, each unit mask member including a plurality of openings and having a length in the first direction longer than a length in second direction perpendicular to the first direction, wherein in the fixing step for fixing each of the plurality of unit mask members to the mask frame, each of two unit mask members next to each other in the second direction among the plurality of unit mask members are positioned to include an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members.

According to the method described above, a vapor deposition mask for large display device relatively inexpensive can be manufactured.

In order to solve the above problems, a manufacturing method of a display device according to the disclosure includes a fixing step for fixing each of a plurality of unit mask members to a mask frame; and a forming step for forming a vapor deposition film on a display region via a plurality of openings on a vapor deposition mask, the vapor deposition mask including the mask frame having frame-shape including an opening, and the plurality of unit mask members, each unit mask member including the plurality of openings and having a length in a first direction longer than a length in second direction perpendicular to the first direction, each of the plurality of unit mask members being fixed to the mask frame, wherein in the fixing step for fixing each of the plurality of unit mask members to the mask frame, each of two unit mask members next to each other in the second direction among the plurality of unit mask members are positioned to include an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members, and in the forming step for forming the vapor deposition film on the display region, a size of the display region where the vapor deposition film is formed is larger than a size of each of the plurality of unit mask members.

According to the method described above, a large display device can be manufactured.

### Advantageous Effects of Disclosure

According to an aspect of the disclosure, a vapor deposition mask for large display device relatively inexpensive, a manufacturing method thereof, and a manufacturing method of a large display device can be provided.

### BRIEF DESCRIPTION OF DRAWINGS

FIG. 1 is a diagram illustrating a schematic configuration of a divided mask provided to a vapor deposition mask for large display device according to a first embodiment.

FIGS. 2A to 2D are each a diagram explaining a schematic configuration and a manufacturing process of the vapor deposition mask for large display device according to the first embodiment.

FIG. 3A and 3B are each a diagram illustrating an example of a method for overlapping divided masks in a vapor deposition mask for large display device according to a second embodiment.

FIG. 4 is a diagram illustrating a method for overlapping divided masks in a vapor deposition mask for large display device according to a third embodiment.

FIG. 5 is a diagram illustrating a method for overlapping divided masks in a vapor deposition mask for large display device according to a fourth embodiment.

FIGS. 6A and 6B are each a diagram illustrating an example of a method for overlapping divided masks in a vapor deposition mask for large display device according to a fifth embodiment.

FIG. 7A is a diagram illustrating a condition where a tension is applied to a vapor deposition mask for large display device in the related art, and FIGS. 7B and 7C are each a diagram illustrating a vapor deposition mask provided with divided masks in the related art.

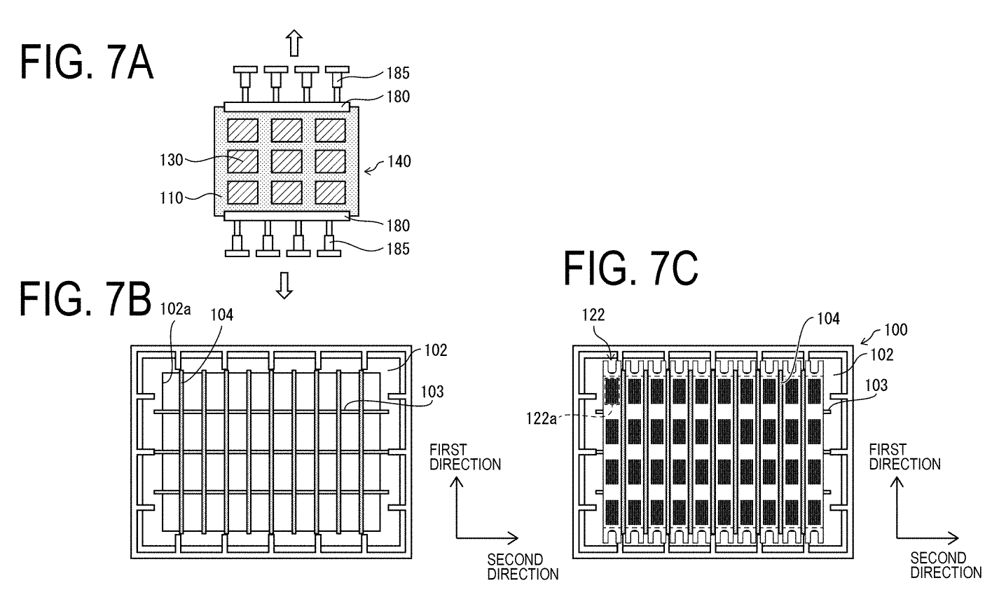

### DESCRIPTION OF EMBODIMENTS

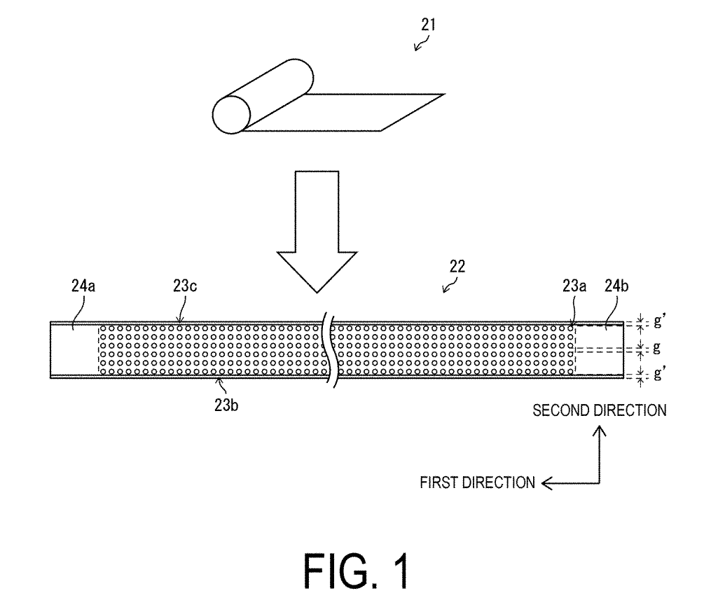

A description follows regarding embodiments of the disclosure, with reference to FIG. 1 to FIG. 6B. Hereinafter, for the sake of the description, a configuration having the same function as a configuration described in a specific embodiment is denoted by the same reference numeral, and its description may be omitted.

In the following embodiments, a vapor deposition mask used in manufacturing an organic EL display device is described as an example, without limitation, and a vapor deposition mask used in manufacturing an inorganic EL display or a QLED display may be adopted, for example.

### First Embodiment

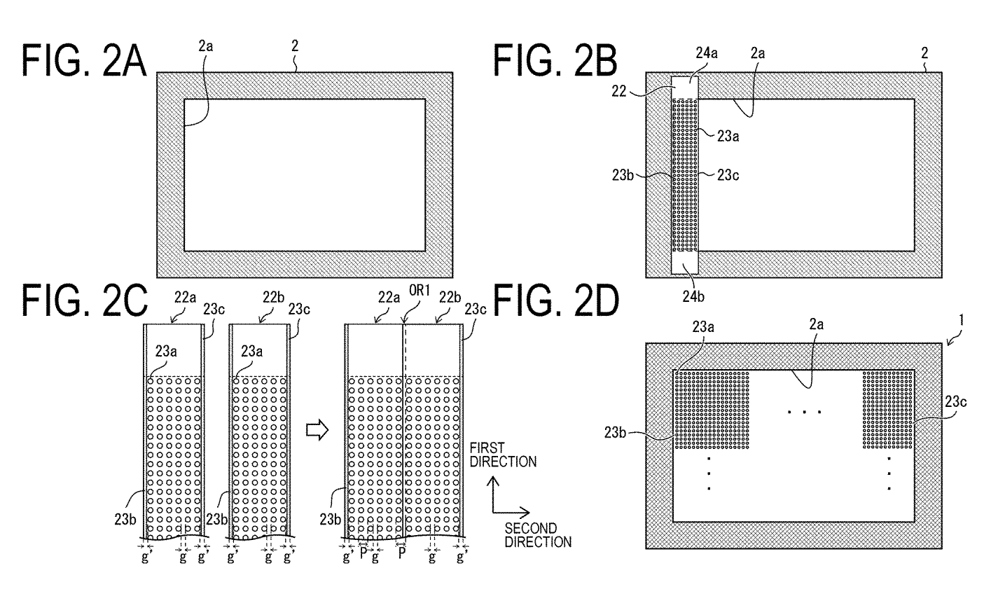

Next, a description is given of the first embodiment of the disclosure based on FIG. 1 to FIG. 2D.

FIG. 1 is a diagram illustrating a schematic configuration of a divided mask (unit mask member) 22.

As illustrated in FIG. 1, in the present embodiment, the divided mask 22 is obtained through an etching process for forming openings 23a on an invar thin plate member 21 rolled shaped having a thickness of 30 μm, and a cutting process for individually separating.

The invar thin plate member 21 for use preferably has the thickness of 10 μm or more and 50 μm or less, and those used in the present embodiment have the thickness of 30 μm.

The present embodiment describes the case, as an example, that the divided mask 22 is formed using the invar thin plate member 21, without limitation, and the divided mask 22 may be formed using a metal thin plate member or an alloy thin plate member other than the invar thin plate member 21.

As illustrated in the figure, the divided mask 22 h has a plurality of openings 23a, and has an elongated shape in which a length in a first direction that is a horizontal direction in the figure is longer than a length in a second direction that is a vertical direction in the figure perpendicular to the first direction.

Both ends of the divided mask 22 in the first direction are regions used in fixing the divided mask 22 to a mask frame, that is, an upper attachment region 24a and a lower attachment region 24b.

In the present embodiment, a shape cut from the invar thin plate member 21 is used as it is for the upper attachment region 24a and the lower attachment region 24b without patterning or the like, but may be patterned into a prescribed shape in a process of forming the openings 23a.

On the other hand, both ends of the divided mask 22 in the second direction are a left end region 23b and a right end region 23c with no opening 23a formed.

The present embodiment describes a case, as an example, that taking an overlapped margin width between the divided masks 22 into account, a width g′ of the left end region 23b in the second direction is the same as a width g′ of the right end region 23c in the second direction, and each of the width g′ of the left end region 23b in the second direction and the width g′ of the right end region 23c in the second direction is slightly smaller than a distance g between the openings 23a next to each other in the second direction, that is, a distance of a planar portion between the openings 23a next to each other in the second direction (in a case of g′<g).

The overlapped margin width which is defined depending on to what degree the width g′ of the left end region 23b in the second direction and the width g′ of the right end region 23c in the second direction are smaller than the distance g between the openings 23a next to each other in the second direction is preferably set to be larger than 0 and smaller than ¼ of the distance g between the openings 23a next to each other in the second direction (0<overlapped margin width (g−g′)<¼×g).

In the present embodiment, the distance g between the openings 23a next to each other in the second direction is 15 μm, but this is an example, and it goes without saying that the distance g between the openings 23a next to each other in the second direction can be adequately changed in conformity to a resolution of the display device or the like, for example.

As described above, the present embodiment describes the example in which the overlapped margin width between the divided masks 22 is ensured, but in a case that the overlapped margin width between the divided masks 22 does not need to be ensured, each of the width g′ of the left end region 23b in the second direction and the width g′ of the right end region 23c in the second direction may be equal to the distance g between the openings 23a next to each other in the second direction (g′=g).

The present embodiment describes the example in which the width g′ of the left end region 23b in the second direction is the same as the width g′ of the right end region 23c in the second direction, but the width of the left end region 23b in the second direction may be different from the width of the right end region 23c in the second direction.

FIGS. 2A to 2D are diagrams explaining a schematic configuration and a manufacturing process of a vapor deposition mask 1 for large display device.

FIG. 2A is a diagram illustrating a schematic configuration of a mask frame 2 having frame-shape including a large opening 2a at a center part thereof provided to the vapor deposition mask 1 for large display device.

FIG. 2B is a diagram illustrating a case that the divided mask 22 illustrated in FIG. 1 is fixed to the mask frame 2 having frame-shape including the large opening 2a at the center part thereof.

In the present embodiment, the divided mask 22 is welded to the mask frame 2 such that the divided mask 22 is fixed to the ask frame 2, without limitation.

In a step of fixing the individual divided masks 22 to the mask frame 2, the divided mask 22 is fixed to the mask frame 2 with a tension being applied to the divided mask 22 in the first direction that is the vertical direction in the figure.

As illustrated in the figure, since the divided mask 22 is has an elongated shape in which the length in the first direction is longer than the length in the second direction perpendicular to the first direction, the length of the divided mask 22 in the second direction is relatively short, and in a stretching machine used in applying a tension in the first direction that is the vertical direction of the divided mask 22 in the figure, the number of drive means such as motors or air cylinders coupled to the holding parts does not need to be increased in order to ensure accuracy thereof, and therefore, a cost of the stretching machine used in the stretching process can be suppressed.

Accordingly, the vapor deposition mask 1 for a relatively inexpensive large display device can be achieved.

FIG. 2C is a diagram explaining an overlapping method of a divided mask 22a and a divided mask 22b which have the same shape as the divided mask 22 illustrated in FIG. 1 and are arranged next to each other in the second direction.

As illustrated in FIG. 2C, the right end region 23c of the divided mask 22a and the left end region 23b of the divided mask 22b are arranged to overlap each other in a planar view and the divided mask 22a and the divided mask 22b are fixed to the mask frame 2.

Each of the width g′ of the right end region 23c of the divided mask 22a in the second direction and the width g′ of the left end region 23b of the divided mask 22b in the second direction is smaller than the distance g between the openings 23a next to each other in the second direction, but a width in the second direction of an overlapping region OR1 where the right end region 23c of the divided mask 22a and the left end region 23b of the divided mask 22b overlap each other in a planar view is equal to the distance g between the openings 23a next to each other in the second direction, that is, a distance of the planar portion between the openings 23a next to each other in the second direction.

Therefore, a pitch P straddling the divided mask 22a and the divided mask 22b between the openings 23a in the second direction is the same as a pitch P between the openings 23a on the divided mask 22a or the divided mask 22b in the second direction.

The pitch P in the second direction between the openings 23a next to each other in the second direction is a sum of a width of the opening 23a in the second direction and the distance g of the planar portion between the openings 23a next to each other.

FIG. 2D is a diagram illustrating a schematic configuration of the vapor deposition mask 1 for large display device completed by arranging such that the openings 23a on the divided mask 22 overlaps the opening 2a of the mask frame 2 in a planar view using the overlapping method illustrated in FIG. 2C.

The present embodiment describes the case, as an example, that a plurality of divided masks 22 having the same shape are used and the left end region 23b and right end region 23c where no opening 23a is formed are overlapped with each other in a planar view, but no limitation is put thereon so long as the identical pitch can be maintained between the openings 23a on a plurality of divided masks 22 overlapping the opening 2a of the mask frame 2 in a planar view.

It goes without saying that the vapor deposition mask 1 for the large display device illustrated in FIG. 2D may be, for example, a vapor deposition mask for forming any of a red light-emitting layer, a green light-emitting layer, and a blue light-emitting layer of an organic EL display device, and the pitch between the openings 23a in the first direction or the pitch between the openings 23a in the second direction depends on a size or resolution of an organic EL display device manufactured.

In a case of an organic EL display device (display device) formed using the vapor deposition mask 1, a display region in the organic EL display device is larger than a size of each of a plurality of divided masks 22, and any of the red light-emitting layer, the green light-emitting layer, and the blue light-emitting layer which are vapor deposition films is formed in the display region via a plurality of opening the vapor deposition mask 1.

The length of the divided mask 22 in the first direction is limited to a prescribed range in consideration of sagging or the like, and therefore, for example, in the case of the divided mask 22 made of the invar thin plate member having the thickness of 30 μm like the present embodiment, the length thereof in the first direction is preferably 1200 mm or less, and the vapor deposition mask 1 for large display device can be preferably used for a large display device of 96 inches or less.

However, it goes without saying that since the length with no sagging in the first direction varies depending on a material or thickness of the divided mask 22, the size of the large display device in which the vapor deposition mask for large display device described above can be preferably used is merely an example.

### Second Embodiment

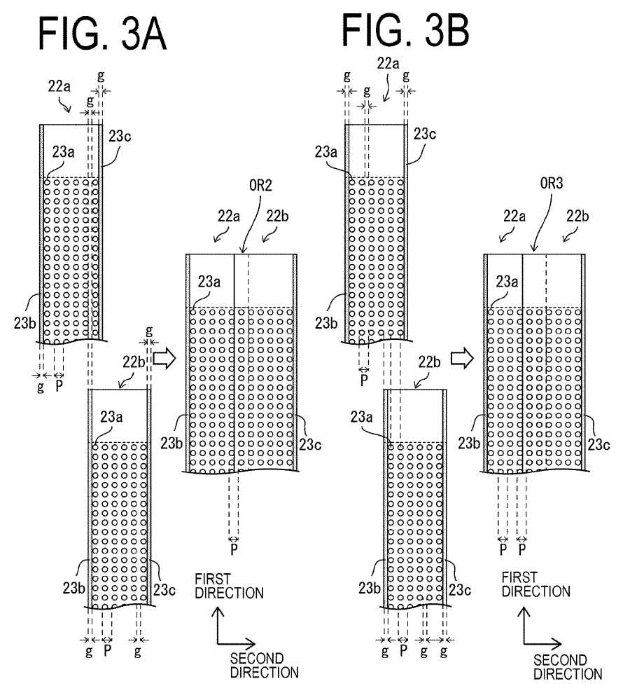

Next, a description is given of the second embodiment of the disclosure will be described based on FIGS. 3A and 3B. The vapor deposition mask for large display device according to the present embodiment is different from the first embodiment in that the openings 23a are overlapped with each other using the divided mask 22a and the divided mask 22b in which the widths g of the left end region 23b and the right end region 23c in the second direction are equal to the distance g between the openings 23a next to each other in the second direction, and other aspects are as described in the first embodiment. For the sake of the description, members having the same functions as the members illustrated in the diagrams in the first embodiment are denoted by the same reference numerals, and descriptions thereof will be omitted.

FIG. 3A illustrates a case that one row of the openings 23a arranged in the first direction is included in an overlapping region OR2 where the divided mask 22a and the divided mask 22b overlap each other in a planar view, and FIG. 3B illustrates a case that two rows of the openings 23a arranged along the first direction are included in an overlapping region OR3 where the divided mask 22a and the divided mask 22b overlap each other in a planar view.

As illustrated in FIG. 3A, in a case that the divided mask 22a and divided mask 22b are overlapped with each other, one row of the openings 23a arranged along the first direction is included in the overlapping region OR2.

A width of the overlapping region OR2 in the second direction is a sum of the width of the opening 23a included in the overlapping region OR2 in the second direction, the width g of the left end region 23b in the second direction, and the width g of the right end region 23c in the second direction.

Even if the overlapping method illustrated in FIG. 3A is used, the identical pitch can be maintained between the openings 23a on a plurality of divided masks 22 overlapping the opening 2a of the mask frame 2 in a planar view.

As illustrated in FIG. 3B, in a case that the divided mask 22a and divided mask 22b are overlapped with each other, two rows of the openings 23a arranged along the first direction is included in the overlapping region OR3.

A width of the overlapping region OR3 in the second direction is a sum of the width of two openings 23a included in the overlapping region OR3 in the second direction, the width g of the left end region 23b in the second direction, the width g of the right end region 23c in the second direction, and the distance g between two openings 23a included in the overlapping region OR3.

Even if the overlapping method illustrated in FIG. 3B is used, the identical pitch can be maintained between the openings 23a on a plurality of divided masks 22 overlapping the opening 2a of the mask frame 2 in a planar view.

The present embodiment describes the case, as an example, that one or two rows of the openings 23a arranged along the first direction are included in the overlapping region, without limitation, and three or more rows of the openings 23a arranged along the first direction may be included in the overlapping region.

The first and second embodiments described above describes the case, as an example, that the width of the overlapping region in the second direction is identical, without limitation, and the overlapping method illustrated in FIG. 3A and the overlapping method illustrated in FIG. 3B may be combined to vary the width the overlapping region in the second direction, for example.

### Third Embodiment

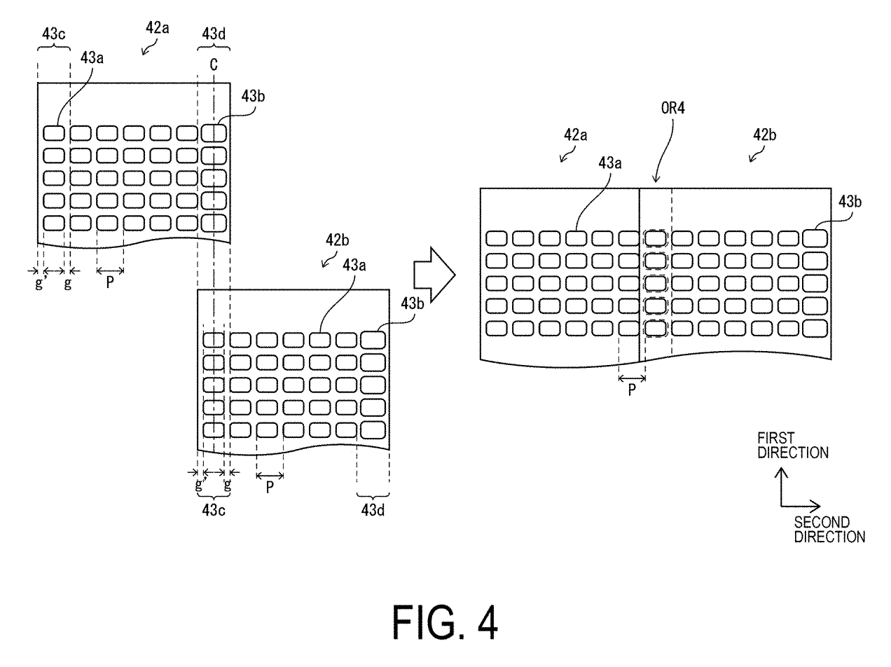

Next, a description is given of the third embodiment of the disclosure based on FIG. 4. The vapor deposition mask for large display device according to present embodiment is different from the first and second embodiments in using a divided mask having a shape different from that used in the first and second embodiments described above, and other aspects are as described in the first and second embodiments. For the sake of the description, members having the same functions as the members illustrated in the diagrams in the first and second embodiments are denoted by the same reference numerals, and descriptions thereof will be omitted.

FIG. 4 is a diagram explaining an overlapping method of a divided mask 42a and a divided mask 42b.

As illustrated in the figure, the divided mask 42a and the divided mask 42b are divided masks having the same shape, and both ends of each of the divided masks 42a and 42b in the second direction are a left end region 43c including openings 43a and a right end region 43d including openings 43b each of which has a size larger than the opening 43a.

The present embodiment describes a case, as an example, that taking an overlapped margin width between the divided mask 42a and the divided mask 42b into account, a width of the left end region 43c in the second direction is smaller than a width of the right end region 43d in the second direction, without limitation, and if the overlapped margin width between the divided mask 42a and the divided mask 42b is not taken into account, the width of the left end region 43c in the second direction may be the same as the width of the right end region 43d in the second direction.

The width of the left end region 43c in the second direction is a sum of the width of the opening 43a in the second direction, a distance g′ on the left side of the opening 43a, and a distance g between the opening 43a and its right-hand opening 43a.

The distance g′ on the left side of the opening 43a in the left end region 43c is smaller than the distance g between the opening 43a in the left end region 43c and its right-hand opening 43a (g′<g).

The distance g between the opening 43a in the left end region 43c and its right-hand opening 43a is also a distance between the openings 43a other than those in the left end region 43c and the right end region 43d on the divided mask 42a and the divided mask 42b.

The overlapped margin width which is defined depending on to what degree the width of the left end region 43c in the second direction is smaller than the width of the right end region 43d in the second direction is preferably set to be larger than 0 and smaller than ¼ of the distance g between the openings 43a other than those in the left end region 43c and the right end region 43d on the divided mask 42a and the divided mask 42b (0<overlapped margin width<¼×g).

As illustrated in the figure, an overlapping region OR4 where the right end region 43d of the divided mask 42a and the left end region 43c of the divided mask 42b overlap each other has a shape of the left end region 43c including the smaller openings 43a.

In the present embodiment, the divided mask 42a and divided mask 42b are positioned in such a way that the identical pitch can be maintained between the openings 43a on a plurality of divided masks 42a and 42b overlapping the opening 2a of the mask frame 2 in a planar view.

A reference sign “C” in FIG. 4 denotes a line connecting centers of the openings 43b in the right end region 43d of the divided mask 42a and centers of the openings 43a in the left end region 43c of the divided mask 42b.

### Fourth Embodiment

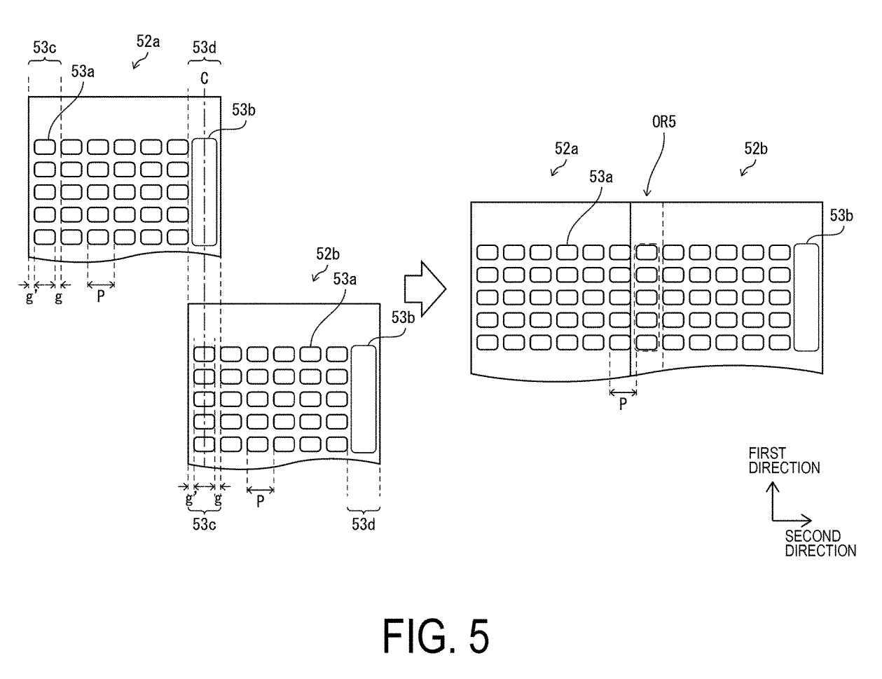

Next, a description is given of the fourth embodiment of the disclosure based on FIG. 5. The vapor deposition mask for large display device according to present embodiment is different from the first to third embodiments in using a divided mask having a shape different from that used in the first to third embodiments described above, and other aspects are as described in the first to third embodiments. For the sake of the description, members having the same functions as the members illustrated in the diagrams in the first to third embodiments are denoted by the same reference numerals, and descriptions thereof will be omitted.

FIG. 5 is a diagram explaining an overlapping method of a divided mask 52a and a divided mask 52b.

As illustrated in the figure, the divided mask 52a and the divided mask 52b are divided masks having the same shape, and both ends of each of the divided masks 52a and 52b in the second direction are a left end region 53c including openings 53a and a right end region 53d including openings 53b each of which has a size larger than the opening 53a.

The opening 53b having a size larger than the opening 53a is shaped to have a width in the first direction larger than the width in the second direction.

The present embodiment describes a case, as an example, that taking an overlapped margin width between the divided mask 52a and the divided mask 52b into account, a width of the left end region 53c in the second direction is smaller than a width of the right end region 53d in the second direction, without limitation, and if the overlapped margin width between the divided mask 52a and the divided mask 52b is not taken into account, the width of the left end region 53c in the second direction may be the same as the width of the right end region 53d in the second direction.

The width of the left end region 53c in the second direction is a sum of the width of the opening 53a in the second direction, a distance g′ on the left side of the opening 53a, and a distance g between the opening 53a and its right-hand opening 43a.

The distance g′ on the left side of the opening 53a in the left end region 53c is smaller than the distance g between the opening 53a in the left end region 53c and its right-hand opening 53a (g′<g).

The distance g between the opening 53a in the left end region 53c and its right-hand opening 53a is also a distance between the openings 53a other than those in the left end region 53c and the right end region 53d on the divided mask 52a and the divided mask 52b.

The overlapped margin width which is defined depending on to what degree the width of the left end region 53c in the second direction is smaller than the width of the right end region 53d in the second direction is preferably set to be larger than 0 and smaller than ¼ of the distance g between the openings 53a other than those in the left end region 53c and the right end region 53d on the divided mask 52a and the divided mask 52b (0<overlapped margin width<¼×g).

As illustrated in the figure, an overlapping region OR5 where the right end region 53d of the divided mask 52a and the left end region 53c of the divided mask 52b overlap each other has a shape of the left end region 53c including the smaller openings 53a.

In the present embodiment, the divided mask 52a and divided mask 52b are positioned in such a way that the identical pitch can be maintained between the openings 53a on a plurality of divided masks 52a and 52b overlapping the opening 2a of the mask frame 2 in a planar view.

A reference sign “C” in FIG. 5 denotes a line connecting centers of the openings 53b in the right end region 53d of the divided mask 52a and centers of the openings 53a in the left end region 53c of the divided mask 52b.

### Fifth Embodiment

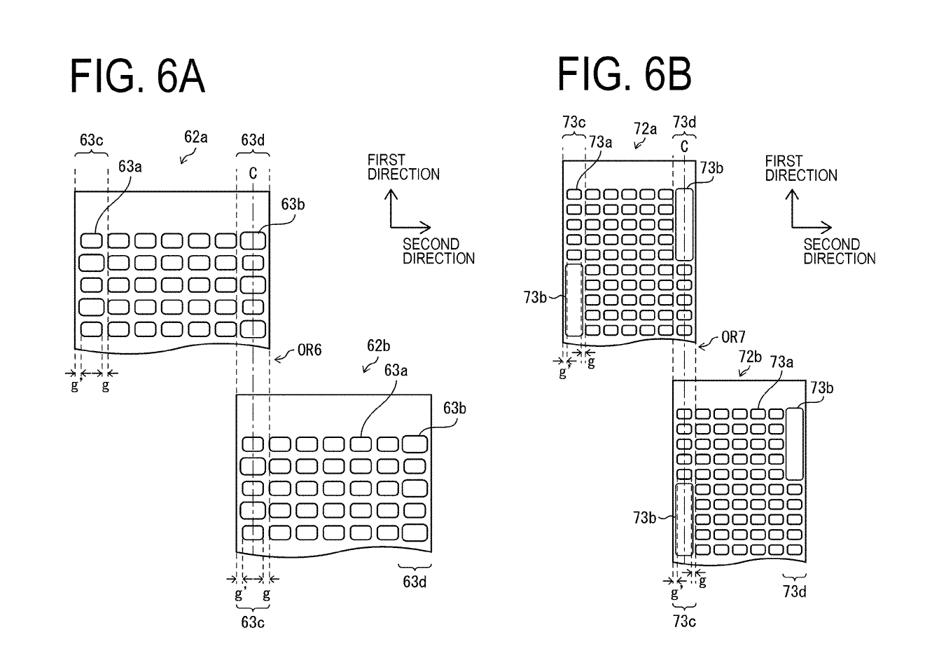

Next, a description is given of the fifth embodiment of the disclosure based on FIG. 6. The vapor deposition mask for large display device according to present embodiment is different from the first to fourth embodiments in using a divided mask having a shape different from that used in the first to fourth embodiments described above, and other aspects are as described in the first to fourth embodiments. For the sake of the description, members having the same functions as the members illustrated in the diagrams in the first to fourth embodiments are denoted by the same reference numerals, and descriptions thereof will be omitted.

FIG. 6A is a diagram explaining an overlapping method of a divided mask 62a and a divided mask 62b.

As illustrated in the figure, the divided mask 62a and the divided mask 62b are divided masks having the same shape, and both ends of each of the divided masks 62a and 62b in the second direction are a left end region 63c including openings 63a and openings 63b alternatively arranged in this order in the first direction, the opening 63b having a size larger than the opening 63a, and a right end region 63d including the openings 63b and the openings 63a alternatively arranged in this order in the first direction.

The present embodiment describes a case, as an example, that taking an overlapped margin width between the divided mask 62a and the divided mask 62b into account, a width of the left end region 63c in the second direction is smaller than a width of the right end region 63d in the second direction, without limitation, and if the overlapped margin width between the divided mask 62a and the divided mask 62b is not taken into account, the width of the left end region 63c in the second direction may be the same as the width of the right end region 63d in the second direction.

The width of the left end region 63c in the second direction is a sum of the width of the opening 63a in the second direction, a distance g′ on the left side of the opening 63a, and a distance g between the opening 63a and its right-hand opening 63a.

The distance g′ on the left side of the opening 63a in the left end region 63c is smaller than the distance g between the opening 63a in the left end region 63c and its right-hand opening 63a (g′<g).

The distance g between the opening 63a in the left end region 63c and its right-hand opening 63a is also a distance between the openings 63a other than those in the left end region 63c and the right end region 63d on the divided mask 62a and the divided mask 62b.

The overlapped margin width which is defined depending on to what degree the width of the left end region 63c in the second direction is smaller than the width of the right end region 63d in the second direction is preferably set to be larger than 0 and smaller than ¼ of the distance g between the openings 63a other than those in the left end region 63c and the right end region 63d on the divided mask 62a and the divided mask 62b (0<overlapped margin width<¼×g).

As illustrated in the figure, an overlapping region OR6 where the right end region 63d of the divided mask 62a and the left end region 63c of the divided mask 62b overlap each other has a shape of the smaller openings 63a.

In the present embodiment, the divided mask 62a and divided mask 62b are positioned in such a way that the identical pitch can be maintained between the openings 63a on a plurality of divided masks 62a and 62b overlapping the opening 2a of the mask frame 2 in a planar view.

A reference sign “C” in FIG. 6A denotes a line connecting centers of the openings 63a and the openings 63b in the right end region 63d of the divided mask 62a and centers of the openings 63a and the openings 63b in the left end region 63c of the divided mask 62b.

FIG. 6B is a diagram explaining an overlapping method of a divided mask 72a and a divided mask 72b.

As illustrated in the figure, the divided mask 72a and the divided mask 72b are divided masks having the same shape, and both ends of each of the divided masks 72a and 72b in the second direction are a left end region 73c including a plurality of openings 73a and an opening 73b arranged in this order in the first direction, the opening 73b having a width in the first direction larger than a width in the second direction, and a right end region 73d including the opening 73b and a plurality of the openings 73a arranged in this order in the first direction, the opening 73b having a width in the first direction larger than a width in the second direction.

The present embodiment describes a case, as an example, that taking an overlapped margin width between the divided mask 72a and the divided mask 72b into account, a width of the left end region 73c in the second direction is smaller than a width of the right end region 73d in the second direction, without limitation, and if the overlapped margin width between the divided mask 72a and the divided mask 72b is not taken into account, the width of the left end region 73c in the second direction may be the same as the width of the right end region 73d in the second direction.

The width of the left end region 73c in the second direction is a sum of the width of the opening 73a in the second direction, a distance g′ on the left side of the opening 73a, and a distance g between the opening 73a and its right-hand opening 73a.

The distance g′ on the left side of the opening 73a in the left end region 73c is smaller than the distance g between the opening 73a in the left end region 73c and its right-hand opening 73a (g′<g).

The distance g between the opening 73a in the left end region 73c and its right-hand opening 73a is also a distance between the openings 73a other than those in the left end region 73c and the right end region 73d on the divided mask 72a and the divided mask 72b.

The overlapped margin width which is defined depending on to what degree the width of the left end region 73c in the second direction is smaller than the width of the right end region 73d in the second direction is preferably set to be larger than 0 and smaller than ¼ of the distance g between the openings 73a other than those in the left end region 73c and the right end region 73d on the divided mask 72a and the divided mask 72b (0<overlapped margin width<¼×g).

As illustrated in the figure, an overlapping region OR7 where the right end region 73d of the divided mask 72a and the left end region 73c of the divided mask 72b overlap each other has a shape of the smaller openings 73a.

In the present embodiment, the divided mask 72a and divided mask 72b are positioned in such a way that the identical pitch can be maintained between the openings 73a on a plurality of divided masks 72a and 72b overlapping the opening 2a of the mask frame 2 in a planar view.

A reference sign “C” in FIG. 6B denotes a line connecting centers of the openings 73a and the openings 73b in the right end region 73d of the divided mask 72a and centers of the openings 73a and the openings 73b in the left end region 73c of the divided mask 72b.

The first to fifth embodiments described above describe the cases, as the examples, that a plurality of divided masks having the same shape are used to perform overlapping, without limitation, and divided masks having different shapes may be overlapped so long as the identical pitch can be maintained between the openings on a plurality of divided masks overlapping the opening 2a of the mask frame 2 in a planar view.

### Supplement

In order to solve the above problems, a vapor deposition mask according to an aspect 1 of the disclosure includes a mask frame having frame-shape including an opening, and a plurality of unit mask members, each unit mask member including a plurality of openings and having a length in a first direction longer than a length in second direction perpendicular to the first direction, each of the plurality of unit mask members being fixed to the mask frame, wherein in the plurality of unit mask members, each of two unit mask members next to each other in the second direction includes an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members.

According to the configuration described above, a vapor deposition mask for large display device relatively inexpensive can be achieved.

In the vapor deposition mask according to an aspect 2 of the disclosure, in the above aspect 1, each of the plurality of unit mask members may include a first end region and a second end region on both ends in the second direction, the first end region and second end region may be regions where the plurality of openings are not formed, a width of each of the first end region and the second end region in the second direction may be equal to or less than a distance in the second direction between two openings next to each other in the second direction among the plurality of openings, and the overlapping region may be a region where the first end region of one unit mask member of two unit mask members next to each other in the second direction among the plurality of unit mask members overlaps, in a planar view, the second end region of the other unit mask member.

According to the configuration described above, a vapor deposition mask for a relatively inexpensive large display device can be achieved.

In the vapor deposition mask according to an aspect 3 of the disclosure, in the above aspect 2, the width of each of the first end region and the second end region in the second direction may be less than the distance in the second direction between two openings next to each other in the second direction, and a difference between the distance in the second direction between two openings next to each other in the second direction and the width of each of the first end region and the second end region in the second direction may be less than a value of ¼ of the distance in the second direction between two openings next to each other in the second direction.

According to the configuration described above, the overlapped margin between the unit mask members can be ensured.

In the vapor deposition mask according to an aspect 4 of the disclosure, in the above aspect 1, each of the plurality of unit mask members may include a first end region and a second end region on both ends in the second direction, the first end region and second end region may be regions where the plurality of openings are not formed, a width of each of the first end region and the second end region in the second direction may be equal to a distance in the second direction between two openings next to each other in the second direction among the plurality of openings, and the overlapping region may be a region where the first end region of one unit mask member of two unit mask members next to each other in the second direction among the plurality of unit mask members and a plurality of openings next to the first end region and arranged along the first direction overlap, in a planar view, the second end region of the other unit mask member and a plurality of openings next to the second end region and arranged along the first direction.

According to the configuration described above, a vapor deposition mask for large display device relatively inexpensive can be achieved.

In the vapor deposition mask according to an aspect 5 of the disclosure, in the above aspect 1, in each of the plurality of unit mask members may include a third end region and a fourth end region on both ends in the second direction, a plurality of first openings may be formed along the first direction in the third end region, each of the first openings having a shape the same as each of the plurality of openings, a plurality of second openings may be formed along the first direction in the fourth end region, each of the second openings being larger than each of the plurality of openings, a width of the third end region in the second direction may be equal to or less than a width of the fourth end region in the second direction, and the overlapping region may be a region where the third end region of one unit mask member of two unit mask members next to each other in the second direction among the plurality of unit mask members overlaps the fourth end region of the other unit mask member in a planar view.

According to the configuration described above, a vapor deposition mask for large display device relatively inexpensive can be achieved.

In the vapor deposition mask according to an aspect 6 of the disclosure, in the above aspect 5, the width of the third end region in the second direction may be less than the width of the fourth end region in the second direction, and a difference between the width of the fourth end region in the second direction and the width of the third end region in the second direction may be less than a value of ¼ of a distance in the second direction between two openings next to each other in the second direction in a portion other than the third end region and the fourth end region in each of the plurality of unit mask members.

According to the configuration described above, the overlapped margin between the unit mask members can be ensured.

In the vapor deposition mask according to an aspect 7 of the disclosure, in the above aspect 1, each of the plurality of unit mask members may include a fifth end region and a sixth end region on both ends in the second direction, a plurality of first openings may be formed along the first direction in the fifth end region, each of the first openings having a shape the same as each of the plurality of openings, a third opening may be formed along the first direction in the sixth end region, the third opening being larger than each of the plurality of openings and having a length in the first direction longer than a length in the second direction, a width of the fifth end region in the second direction may be equal to or less than a width of the sixth end region in the second direction, and the overlapping region may be a region where the fifth end region of one unit mask member of two unit mask members next to each other in the second direction among the plurality of unit mask members overlaps the sixth end region of the other unit mask member in a planar view.

According to the configuration described above, a vapor deposition mask for large display device relatively inexpensive can be achieved.

In the vapor deposition mask according to an aspect 8 of the disclosure, in the above aspect 7, the width of the fifth end region in the second direction may be less than the width of the sixth end region in the second direction, and a difference between the width of the sixth end region in the second direction and the width of the fifth end region in the second direction may be less than a value of ¼ of a distance in the second direction between two openings next to each other in the second direction in a portion other than the fifth end region and the sixth end region in each of the plurality of unit mask members.

According to the configuration described above, the overlapped margin between the unit mask members can be ensured.

In the vapor deposition mask according to an aspect 9 of the disclosure, in the above aspect 1, each of the plurality of unit mask members may include a seventh end region and a eighth end region on both ends in the second direction, a plurality of first openings and a plurality of second opening may be alternately formed in this order along the first direction in the seventh end region, each of the first openings having a shape the same as each of the plurality of openings, each of the second openings being larger than each of the plurality of openings, the plurality of second openings and the plurality of first openings may be alternately formed in this order along the first direction in the eighth end region, a width of the seventh end region in the second direction may be equal to or less than a width of the eighth end region in the second direction, and the overlapping region may be a region where the seventh end region of one unit mask member of two unit mask members next to each other in the second direction among the plurality of unit mask members overlaps the eighth end region of the other unit mask member in a planar view.

According to the configuration described above, a vapor deposition mask for large display device relatively inexpensive can be achieved.

In the vapor deposition mask according to an aspect 10 of the disclosure, in the above aspect 9, the width of the seventh end region in the second direction may be less than the width of the eighth end region in the second direction, and a difference between the width of the eighth end region in the second direction and width of the seventh end region in the second direction may be less than a value of ¼ of a distance in the second direction between two openings next to each other in the second direction in a portion other than the seventh end region and the eighth end region in each of the plurality of unit mask members.

According to the configuration described above, the overlapped margin between the unit mask members can be ensured.

In the vapor deposition mask according to an aspect 11 of the disclosure, in the above aspect 1, each of the plurality of unit mask members may include a ninth end region and a tenth end region on both ends in the second direction, a plurality of first openings and a third opening may be formed in this order along the first direction in the ninth end region, each of the first openings having a shape the same as each of the plurality of openings, the third opening being larger than each of the plurality of openings and having a length in the first direction longer than a length in the second direction, the third opening and the plurality of first openings may be formed in this order along the first direction in the tenth end region, and a width of the ninth end region in the second direction may be equal to or less than a width of the tenth end region in the second direction, and the overlapping region may be a region where the ninth end region of one unit mask member of two unit mask members next to each other in the second direction among the plurality of unit mask members overlaps the tenth end region of the other unit mask member in a planar view.

According to the configuration described above, a vapor deposition mask for large display device relatively inexpensive can be achieved.

In the vapor deposition mask according to an aspect 11 of the disclosure, in the above aspect 12, the width of the ninth end region in the second direction may be less than the width of the tenth end region in the second direction, and a difference between the width of the tenth end region in the second direction and the width of the ninth end region in the second direction may be less than a value of ¼ of a distance in the second direction between two openings next to each other in the second direction in a portion other than the ninth end region and the tenth end region in each of the plurality of unit mask members.

According to the configuration described above, the overlapped margin between the unit mask members can be ensured.

A display device according to an aspect 13 of the disclosure is formed using the vapor deposition mask described in any one of the aspects 1 to 12, wherein a display region in the display device may be larger than each of the plurality of unit mask members, and a vapor deposition film may be formed in the display region via the plurality of openings on the vapor deposition mask.

According to the configuration described above, a large display device can be achieved.

In order to solve the above problems, a manufacturing method of a vapor deposition mask according to an aspect 14 of the disclosure includes a fixing step for fixing each of a plurality of unit mask members to a mask frame having frame-shape including an opening with a tension being applied in the first direction, each unit mask member including a plurality of openings and having a length in the first direction longer than a length in second direction perpendicular to the first direction, wherein in the fixing step for fixing each of the plurality of unit mask members to the mask frame, each of two unit mask members next to each other in the second direction among the plurality of unit mask members are positioned to include an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members.

According to the method described above, a vapor deposition mask for large display device relatively inexpensive can be manufactured.

In order to solve the above problems, a manufacturing method of a display device according to an aspect 15 of the disclosure includes: a fixing step for fixing each of a plurality of unit mask members to a mask frame; and a forming step for forming a vapor deposition film on a display region via a plurality of openings on a vapor deposition mask, the vapor deposition mask including the mask frame having frame-shape including an opening, and the plurality of unit mask members, each unit mask member including the plurality of openings and having a length in a first direction longer than a length in second direction perpendicular to the first direction, each of the plurality of unit mask members being fixed to the mask frame, wherein in the fixing step for fixing each of the plurality of unit mask members to the mask frame, each of two unit mask members next to each other in the second direction among the plurality of unit mask members are positioned to include an overlapping region where the two unit mask members partially overlap each other in a planar view, and a pitch in the second direction between the plurality of openings on the plurality of unit mask members each including the overlapping region is the same as a pitch in the second direction between the plurality of openings in a region other than the overlapping region in each of the plurality of unit mask members, and in the forming step for forming the vapor deposition film on the display region, a size of the display region where the vapor deposition film is formed is larger than a size of each of the plurality of unit mask members.

According to the method described above, a large display device can be manufactured.

### Supplemental Note

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the present embodiments.

### INDUSTRIAL APPLICABILITY

The disclosure can be used for a vapor deposition mask, a manufacturing method of a vapor deposition mask, a display device, and a manufacturing method of a display device.

### REFERENCE SIGNS LIST

1 Vapor deposition mask
2 Mask frame
2a Opening
21 Invar thin plate member
22, 22a, 22b Divided mask (unit mask member)
23a Opening
23b Left end region (first end region)
23c Right end region (second end region)
42a, 42b Divided mask (unit mask member)
43a, 63a Opening (first opening)
43b, 63b Opening (second opening)
43c Left end region (third end region)
43d Right end region (fourth end region)
52a, 52b Divided mask (unit mask member)
53a, 73a Opening (first opening)
53b, 73b Opening (third opening)
53c Left end region (fifth end region)
53d Right end region (sixth end region)
62a, 62b Divided mask (unit mask member)
63c Left end region (seventh end region)
63d Right end region (eighth end region)
72a, 72b Divided mask (unit mask member)
73c Left end region (ninth end region)
73d Right end region (tenth end region)
OR1 to OR7 Overlapping region

1. A vapor deposition mask comprising:
a mask frame having frame-shape including an opening; and
a plurality of unit mask members, each unit mask member including a plurality of openings and having a length in a first direction longer than a length in second direction perpendicular to the first direction, each of the plurality of unit mask members being fixed to the mask frame,
wherein in the plurality of unit mask members, each of two unit mask members next to each other in the second direction includes an overlapping region where the two unit mask members partially overlap each other in a planar view,
a pitch in the second direction between the plurality of openings on the plurality of unit mask members each including the overlapping region is the same as a pitch in the second direction between the plurality of openings in a region other than the overlapping region in each of the plurality of unit mask members,
each of the plurality of unit mask members includes a first end region and a second end region on both ends in the second direction,
the first end region and the second end region are regions where the plurality of openings are not formed,
a width of each of the first end region and the second end region in the second direction is equal to a distance in the second direction between two openings next to each other in the second direction among the plurality of openings, and
the overlapping region is a region where the first end region of one unit mask member of two unit mask members next to each other in the second direction among the plurality of unit mask members and a plurality of openings next to the first end region and arranged along the first direction overlap, in a planar view, the second end region of the other unit mask member and a plurality of openings next to the second end region and arranged along the first direction.

2-12. (canceled)

13. A display device formed using the vapor deposition mask according to claim 1,
wherein a display region in the display device is larger than each of the plurality of unit mask members, and
a vapor deposition film is formed in the display region via the plurality of openings on the vapor deposition mask.

14-15. (canceled)

16. A vapor deposition mask comprising:
a mask frame having frame-shape including an opening; and
a plurality of unit mask members, each unit mask member including a plurality of openings and having a length in a first direction longer than a length in second direction perpendicular to the first direction, each of the plurality of unit mask members being fixed to the mask frame,
wherein in the plurality of unit mask members, each of two unit mask members next to each other in the second direction includes an overlapping region where the two unit mask members partially overlap each other in a planar view,
a pitch in the second direction between the plurality of openings on the plurality of unit mask members each including the overlapping region is the same as a pitch in the second direction between the plurality of openings in a region other than the overlapping region in each of the plurality of unit mask members,
each of the plurality of unit mask members includes a third end region and a fourth end region on both ends in the second direction,
a plurality of first openings are formed along the first direction in the third end region, each of the first openings having a shape the same as each of the plurality of openings,
a plurality of second openings are formed along the first direction in the fourth end region, each of the second openings being larger than each of the plurality of openings,
a width of the third end region in the second direction is equal to or less than a width of the fourth end region in the second direction, and
the overlapping region is a region where the third end region of one unit mask member of two unit mask members next to each other in the second direction among the plurality of unit mask members overlaps the fourth end region of the other unit mask member in a planar view.

17. The vapor deposition mask according to claim 16,
wherein the width of the third end region in the second direction is less than the width of the fourth end region in the second direction, and
a difference between the width of the fourth end region in the second direction and the width of the third end region in the second direction is less than a value of ¼ of a distance in the second direction between two openings next to each other in the second direction in a portion other than the third end region and the fourth end region in each of the plurality of unit mask members.

18. The vapor deposition mask according to claim 16,
wherein the plurality of first openings and a plurality of second opening are alternately formed in this order along the first direction in the third end region, each of the first openings having a shape the same as each of the plurality of openings, each of the second openings being larger than each of the plurality of openings, and
the plurality of second openings and the plurality of first openings are alternately formed in this order along the first direction in the fourth end region.

19. The vapor deposition mask according to claim 18,
wherein the width of the third end region in the second direction is less than the width of the fourth end region in the second direction, and
a difference between the width of the fourth end region in the second direction and the width of the third end region in the second direction is less than a value of ¼ of a distance in the second direction between two openings next to each other in the second direction in a portion other than the third end region and the fourth end region in each of the plurality of unit mask members.

20. A display device formed using the vapor deposition mask according to claim 16,
wherein a display region in the display device is larger than each of the plurality of unit mask members, and
a vapor deposition film is formed in the display region via the plurality of openings on the vapor deposition mask.

21. A vapor deposition mask comprising:
a mask frame having frame-shape including an opening; and
a plurality of unit mask members, each unit mask member including a plurality of openings and having a length in a first direction longer than a length in second direction perpendicular to the first direction, each of the plurality of unit mask members being fixed to the mask frame,
wherein in the plurality of unit mask members, each of two unit mask members next to each other in the second direction includes an overlapping region where the two unit mask members partially overlap each other in a planar view,
a pitch in the second direction between the plurality of openings on the plurality of unit mask members each including the overlapping region is the same as a pitch in the second direction between the plurality of openings in a region other than the overlapping region in each of the plurality of unit mask members,
each of the plurality of unit mask members includes a fifth end region and a sixth end region on both ends in the second direction,
a plurality of first openings are formed along the first direction in the fifth end region, each of the first openings having a shape the same as each of the plurality of openings,
a third opening is formed along the first direction in the sixth end region, the third opening being larger than each of the plurality of openings and having a length in the first direction longer than a length in the second direction,
a width of the fifth end region in the second direction is equal to or less than a width of the sixth end region in the second direction, and
the overlapping region is a region where the fifth end region of one unit mask member of two unit mask members next to each other in the second direction among the plurality of unit mask members overlaps the sixth end region of the other unit mask member in a planar view.

22. The vapor deposition mask according to claim 21,
wherein the width of the fifth end region in the second direction is less than the width of the sixth end region in the second direction, and
a difference between the width of the sixth end region in the second direction and the width of the fifth end region in the second direction is less than a value of ¼ of a distance in the second direction between two openings next to each other in the second direction in a potion other than the fifth end region and the sixth end region in each of the plurality of unit mask members.

23. The vapor deposition mask according to claim 21,
wherein the plurality of first openings and a third opening are formed in this order along the first direction in the fifth end region, each of the first openings having a shape the same as each of the plurality of openings, the third opening being larger than each of the plurality of openings and having a length in the first direction longer than a length in the second direction, and
the third opening and the plurality of first openings are formed in this order along the first direction in the sixth end region.

24. The vapor deposition mask according to claim 23,
wherein the width of the fifth end region in the second direction is less than the width of the sixth end region in the second direction, and
a difference between the width of the sixth end region in the second direction and the width of the fifth end region in the second direction is less than a value of ¼ of a distance in the second direction between two openings next to each other in the second direction in a portion other than the fifth end region and the sixth end region in each of the plurality of unit mask members.

25. A display device formed using the vapor deposition mask according to claim 21,
wherein a display region in the display device is larger than each of the plurality of unit mask members, and
a vapor deposition film is formed in the display region via the plurality of openings on the vapor deposition mask.
